(19) United States
(12) Patent Application Publication
(10) Pub. No.: US 2010/0147137 A1
(43) Pub. Date: Jun. 17, 2010

(54) Digital sound effect processing device

(75) Inventor: Jin-Yi Huang, Tainan Hsien (TW)

Correspondence Address: BACON & THOMAS, PLLC, 625 SLATERS LANE, FOURTH FLOOR, ALEXANDRIA, VA, 22314-1176, US

(73) Assignee: Ya Horng Electronic Co., Ltd, Tainan Hsien (TW)

(21) Appl. No.: 12/314,539

(22) Filed: Dec. 12, 2008

(51) Int. Cl. G10H 7/00; H03G 3/00

(52) U.S. Cl. 84/603; 381/61

(57) ABSTRACT

A digital sound effect processing device includes an analog/digital converter, a digital signal processor, and a digital/analog converter. The analog/digital converter converts analog frequency signals input by a signal input unit into digital signals to be output. The digital signal processor has one input terminal connected with the analog/digital converter and another input terminal connected with a music access unit for collecting digital audio data input by the analog/digital converter and original music data stored in the music access unit and changing the broadcasting sound effects of the original music data according to the digital audio data and then digitally outputting the sound effects. The digital/analog converter converts the digital music output by the digital signal processor into analog music to be broadcast through a loudspeaker.

### BACKGROUND OF THE INVENTION

1. Field of the Invention

This invention relates to a digital sound effect processing device, particularly to one employed to take the place of a conventional DJ to control the rotating speed of an imitative vinyl record for making sound effects.

2. Description of the Prior Art

In recent years, we can often see a DJ manually control the rotating speed of a vinyl record on a turntable to produce special sound effects for elevating atmosphere of the site. However, since technology has been improved continuously, conventional vinyl records are not easy to be found and due to insufficient source and the price of a vinyl record is high. In addition, it requires lots of trouble to continuously change a vinyl record.

### SUMMARY OF THE INVENTION

The objective of this invention is to offer a digital sound effect processing device employed to take the place of vinyl records for making sound effects.

The digital sound effect processing device in the present invention includes an analog/digital converter having one input terminal connected with a signal input unit for receiving analog frequency signals of the signal input unit and then converting the analog frequency signals into digital signals to be output. The digital sound effect processing device further includes a digital signal processor, which has one input terminal connected with the analog/digital converter and another input terminal connected with a music access unit for collecting digital audio data input by the analog/digital converter and original music data stored in the music access unit and then changing broadcasting sound effects of the original music data of the music access unit and outputting the sound effects in a digital mode. The digital sound effect processing device further includes a digital/analog converter, which has an input terminal connected with the output terminal of the preceding digital signal processor for converting the digital music output by the digital signal processor into analog music to be broadcast through a loudspeaker. By so designing, the digital sound effect processing device of this invention can take the place of a DJ who controls the rotating speed of an imitative vinyl record for making sound effects.

### BRIEF DESCRIPTION OF DRAWINGS

This invention will be better understood by referring to the accompanying drawings, wherein:

FIG. 1 is a block diagram of a digital sound effect processing device in the present invention; and

FIG. 2 is another block diagram of a digital sound effect processing device in the present invention.

### DETAILED DESCRIPTION OF THE PREFERRED EMBODIMENT

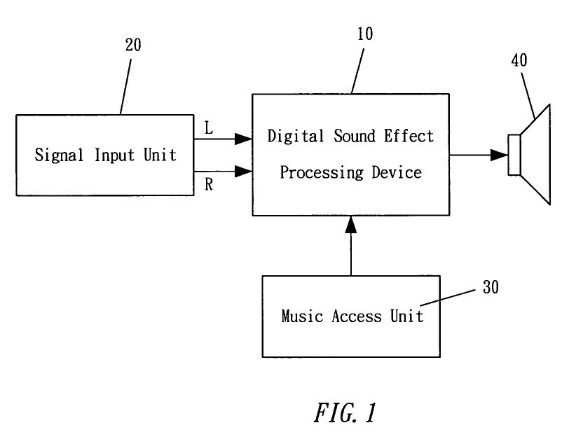

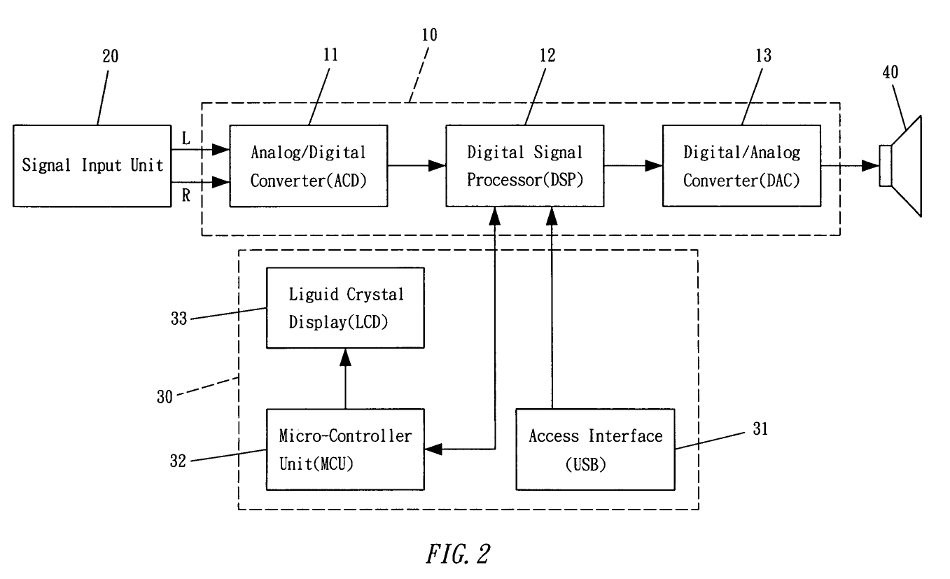

A preferred embodiment of a digital sound effect processing device 10 in the present invention, as shown in FIGS. 1 and 2, includes an analog/digital converter (ADC) 11, a digital signal processor (DSP) 12 and a digital/analog converter (DAC) 13 as main components combined together.

The analog/digital converter 11 has one input terminal connected with the output terminal of a signal input unit 20. The signal input unit 20 can be a turntable plus an imitative vinyl record (an audio disk) on the turntable to let a DJ touch the imitative vinyl record for producing high and low frequency to be output, or can be a CD player for changing output frequency by controlling switches of the CD player. After the analog/digital converter 11 receives analog frequency signals of the signal input unit 20, the analog frequency signals will be converted into digital signals to be output.

The digital signal processor 12 has one input terminal connected with the output terminal of the analog/digital converter 11 and another input terminal connected with the output terminal of a music access unit 30 for collecting digital audio data input by the analog/digital converter 11 and the original music data stored in the music access unit 30. Then according to the digital audio data, the broadcasting sound effects of the original music data of the music access unit 30 are changed and then output as the sound effects in a digital mode.

The digital/analog converter 13 has an input terminal connected with the digital signal processor 12 for converting the digital music output by the digital signal processor 12 into analog music to be broadcast through a loudspeaker 40.

The music access unit 30 mentioned above contains an access interface 31, a micro-controller unit (MCU) 32 and a liquid crystal display (LCD) 33. The access interface 31, such as a USB connecting port, is used for connecting a music storage unit, such as an MP3 or a CD player. The micro-controller unit 32 is two-way connected with the digital signal processor 12 so that, through the digital signal processor 12, the micro-controller unit 32 can function to pick out songs from the music storage unit (the MP3 or the CD player) connected with the access interface 31 and also to adjust the volume of sound. Moreover, the liquid crystal display 33 has an input terminal connected with the output terminal of the micro-controller unit 32 so that the songs picked out by the micro-controller unit 32 and the volume of sound can be shown on the liquid crystal display 33.

Thus, the signal input unit 20 (an imitative vinyl record, a CD broadcaster or the like), which is formed with a left and a right sound channel, can function to input analog audio data with different high and low frequencies to the analog/digital converter 11. Simultaneously, the analog/digital converter 11 will convert the input analog audio data into digital audio data to be output, and then the input digital audio data inputs signals are fed to the digital signal processor 12. Subsequently, according to audio data, the digital signal processor 12 will change the broadcasting sound effects of the digital audio data input by the analog/digital converter 11 as well as the original music data of the music access unit 30 and then digitally output the changed original music data to the digital/analog converter 13, which will synchronously convert the input original music data into analog music to be broadcast through the a loudspeaker 40.

Therefore, in accordance with this invention, the steps for a DJ to make sound effects are as follows:

1. A first step is to have a music storing MP3 insertion connected with the access interface 31 and have the micro-controller unit 32 pick out songs and adjusting the volume of sound.

2. A second step is to have the signal input unit 20 adjust and change high and low frequency and output the frequency to the digital sound effect processing device 10 to be processed. Thus, the music picked out by the micro-controller unit 32 can be changed to make sound effects to be output, having the same sound effects as those made by a DJ manually touching conventional vinyl records.

While the preferred embodiment of the invention has been described above, it will be recognized and understood that various modifications may be made therein and the appended claims are intended to cover all such modifications that may fall within the spirit and scope of the invention.

I claim:

1. A digital sound effect processing device comprising:
an analog/digital converter having one input terminal connected with a signal input unit, said analog/digital converter receiving analog frequency signals from said signal input unit and converting said analog frequency signals into digital signals to be output;
a digital signal processor having one input terminal connected with said analog/digital converter and another input terminal connected with a music access unit, said digital signal processor collecting digital audio data input by said analog/digital converter and original music data stored in said music access unit, said digital signal processor changing broadcasting music sound effects of said original music data of said music access unit according to said digital audio data and then outputting the sound effects in a digital mode; and
a digital/analog converter having one input terminal connected with an output terminal of said digital signal processor, said digital/analog converter converting digital music output by said digital signal processor into analog music to be broadcast through a loudspeaker.

2. The digital sound effect processing device as claimed in claim 1, wherein said digital input unit is a turntable plus an imitative vinyl record on said turntable to produce high and low frequency to be output.

3. The digital sound effect processing device as claimed in claim 1, wherein said signal input unit is a CD broadcaster that changes output frequency by controlling a switch.

4. The digital sound effect processor device as claimed in claim 1, wherein said music access unit is provided with an access interface, a micro-controller unit and a liquid crystal display, said access interface is connected with a music storage unit, said micro-controller unit is two-way connected with said digital signal processor, through said digital signal processor, said micro-controller unit picks out songs from said music storage unit connected with said access interface and adjusts volume of sounds, and said liquid crystal display has one input terminal connected with an output terminal of said micro-controller unit for displaying songs and volume of sounds picked by said micro-controller unit.
